(19) United States
(12) Patent Application Publication
(10) Pub. No.: US 2020/0088257 A1
(43) Pub. Date: Mar. 19, 2020

(54) PRESSING STRUCTURE AND PRESSING UNIT

(71) Applicant: NHK Spring Co., Ltd., Yokohama-shi (JP)

(72) Inventors: Hironobu Imaizumi, Yokohama-shi (JP); Norihiro Tajima, Yokohama-shi (JP); Yoshio Yamada, Yokohama-shi (JP); Shuji Takahashi, Yokohama-shi (JP); Atsushi Yoneoka, Yokohama-shi (JP)

(21) Appl. No.: 16/466,833

(22) PCT Filed: Dec. 6, 2017
(86) PCT No.: PCT/JP2017/043879

§ 371 Date: Jun. 5, 2019

(30) Foreign Application Priority Data
Dec. 7, 2016 (JP) 2016-237709

(51) Int. Cl. F16F 1/18; H01L 23/40

(52) U.S. Cl. CPC F16F 1/18; F16F 2230/0005; H01L 23/40

(57) ABSTRACT

A pressing structure is arranged between a first pressed body and a second pressed body opposite to the first pressed body and presses the first pressed body and second pressed body. The pressing structure includes a spring member including: a base portion formed of a single strip-like member and having a curved principal surface; two extended portions extending respectively from end portions of the base portion and curved in a form inverse of a curving form of the base portion; and two bent portions extending respectively from end portions of the two extended portions, the end portions being at sides opposite to sides connected to the base portion, the two bent portions being curved in a form inverse of the curving form of the extended portions; and the maximum thickness of the extended portions and bent portions is smaller than the maximum thickness of the base portion.

### FIELD

The present invention relates to a pressing structure and a pressing unit.

### BACKGROUND

A spring member, which is provided between two pressed bodies, and presses one or both of these pressed bodies by applying pressure thereto, has been known. This spring member is used in, for example, a power converting apparatus having a stacked structure formed by alternately stacking semiconductor modules and cooling tubes that cool the semiconductor modules on each other (see, for example, Patent Literature 1).

This power converting apparatus includes: at a stacking direction end portion of the semiconductor modules and cooling tubes, a spring member that generates pressing force along a stacking direction; and an abutting plate, which is provided between this spring member and the stacked structure, and is for generating a uniform pressing force in the stacking direction. A power converting apparatus having such a configuration enables its semiconductor modules to be sufficiently cooled, because adjacent ones of the semiconductor modules and cooling tubes closely contact each other by means of the pressing force of its spring member.

### CITATION LIST

### Patent Literature

Patent Literature 1: Japanese Laid-open Patent Publication No. 2014-011936

### SUMMARY

### Technical Problem

Demanded for a spring member for a pressing use as described above are: a long elastic stroke relative to a load for absorption of the tolerance or the like of a target to be pressed; and pressing in a uniform surface pressure distribution while generating a uniform stress. Methods of increasing the length of the elastic stroke include a method where plural plate-like spring members are placed on top of one another in a stroke direction. However, hysteresis caused by friction between the spring members and complexity of the assembly are problematic, making it impossible to place too many spring members on top of one another and limiting the possible range of increase in the length of the elastic stroke.

The present invention has been made in view of the above, and an object thereof is to provide a pressing structure and a pressing unit that have a long elastic stroke relative to a load and are able to press a target while generating a uniform stress.

### Solution to Problem

To solve the above-described problem and achieve the object, a pressing structure according to the present invention is arranged between a first pressed body and a second pressed body opposite to the first pressed body and presses the first pressed body and the second pressed body, and includes a spring member including: a base portion formed of a single strip-like member and having a curved principal surface; two extended portions extending respectively from end portions of the base portion and curved in a form inverse of a curving form of the base portion; and two bent portions extending respectively from end portions of the two extended portions, the end portions being at sides opposite to sides connected to the base portion, the two bent portions being curved in a form inverse of the curving form of the extended portions, wherein a maximum thickness of the extended portions and bent portions is smaller than a maximum thickness of the base portion.

Moreover, in the above-described pressing structure according to the present invention, the base portion decreases in thickness toward the extended portions.

Moreover, in the above-described pressing structure according to the present invention, a locus formed of a collection of curvature center points of one of principal surfaces of the base portion and a locus formed of a collection of curvature center points of the other principal surface are different from each other.

Moreover, in the above-described pressing structure according to the present invention, a ratio, d₁/d₂, between the maximum thickness d₁ of the base portion and the maximum thickness d₂ of the extended portions and bent portions is equal to or larger than 1.5 and equal to or smaller than 3.0.

Moreover, in the above-described pressing structure according to the present invention, on a side surface connected to two opposite principal surfaces of the spring member, the side surface being at a side that is curved according to the curving forms of the base portion, extended portions, and bent portions, a shear surface is formed only on a principal surface side where the base portion and bent portions are concave and a fracture surface is formed only on a principal surface side where the base portion and bent portions are convex.

Moreover, a pressing unit according to the present invention includes: a first pressed body; a second pressed body arranged opposite to the first pressed body; and the pressing structure according to the above-described invention that is arranged between the first pressed body and the second pressed body and presses the first pressed body and the second pressed body.

### Advantageous Effects of Invention

The present invention has an effect of achieving a long elastic stroke relative to a load and enabling a target to be pressed while a uniform stress is being generated.

### BRIEF DESCRIPTION OF DRAWINGS

FIG. 1 is a side view schematically illustrating a pressing unit having, used therein, a spring member according to a first embodiment of the present invention.

FIG. 2 is a perspective view illustrating a configuration of the spring member according to the first embodiment of the present invention.

FIG. 3 is a side view illustrating a configuration of the spring member according to the first embodiment of the present invention.

FIG. 4 is a side view illustrating a configuration of a material for manufacturing the spring member according to the first embodiment of the present invention.

FIG. 5 is a side view illustrating a configuration of main parts of the spring member according to the first embodiment of the present invention.

FIG. 6 is a sectional view along an A-A line illustrated in FIG. 5.

FIG. 7 is a side view illustrating a configuration of main parts of a conventional spring member.

FIG. 8A is a diagram for explanation of a method of manufacturing a base material for formation of a conventional spring member.

FIG. 8B is a diagram for explanation of the method of manufacturing the base material for the formation of the conventional spring member.

FIG. 8C is a diagram for explanation of the method of manufacturing the base material for the formation of the conventional spring member.

FIG. 9A is a diagram for explanation of a method of manufacturing a base material for formation of a conventional spring member.

FIG. 9B is a diagram for explanation of the method of manufacturing the base material for the formation of the conventional spring member.

FIG. 9C is a diagram for explanation of the method of manufacturing the base material for the formation of the conventional spring member.

FIG. 10 is a side view illustrating another example of a base material for manufacturing the spring member according to the first embodiment of the present invention.

FIG. 11 is a side view illustrating another example of the base material for manufacturing the spring member according to the first embodiment of the present invention.

FIG. 12 is a schematic diagram illustrating a configuration of main parts of a power converting apparatus according to a second embodiment of the present invention.

FIG. 13 is a schematic diagram illustrating a configuration of main parts of a power converting apparatus according to a modified example of the second embodiment of the present invention.

FIG. 14 is a schematic diagram illustrating a configuration of main parts of an electric double layer capacitor according to a third embodiment of the present invention.

### DESCRIPTION OF EMBODIMENTS

Described in the following description as modes for carrying out the present invention (hereinafter, referred to as “embodiments”) are pressing units each having a spring member used therein. Furthermore, the invention is not limited by these embodiments. Moreover, throughout the drawings, any portions that are the same are assigned with the same reference sign. In addition, it needs to be noted that the drawings are schematic, and that relations between thicknesses and widths of components, and ratios or the like among the components are different from the actual ones. Furthermore, the drawings include a portion that differs in dimensions and ratios among the drawings. Dimensions or the like “being equivalent” means that the dimensions or the like are equivalent in terms of design, and dimensions or the like of the actual components include manufacturing errors.

### First Embodiment

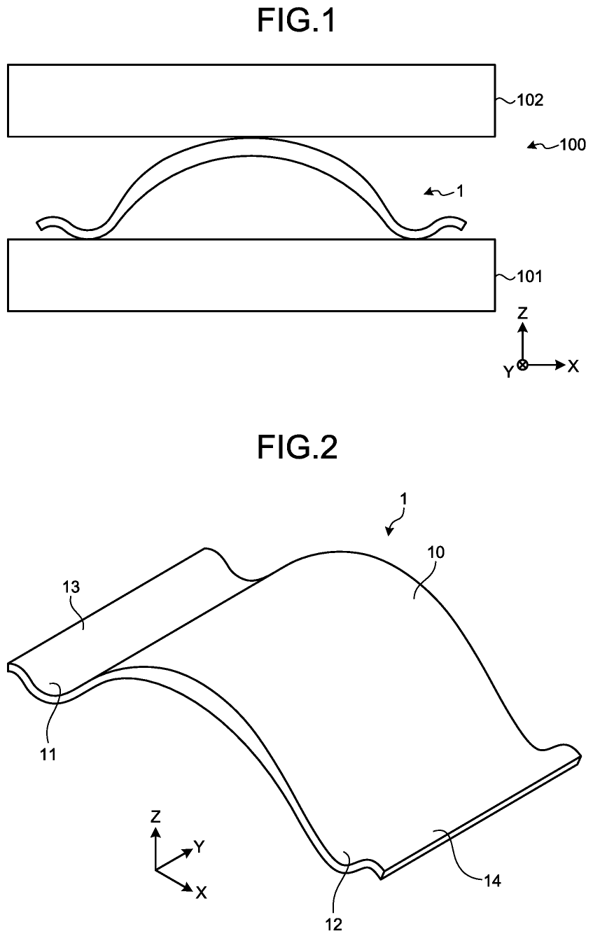

FIG. 1 is a side view schematically illustrating a pressing unit having, used therein, a spring member according to a first embodiment of the present invention. A pressing structure 100 according to the first embodiment of the present invention has a spring member 1 arranged between a first pressed body 101 and a second pressed body 102 that are opposite to each other. The pressing unit according to the first embodiment has the pressing structure 100 arranged between the first pressed body 101 and second pressed body 102 that are opposite to each other. The pressing structure 100 applies pressure, by means of elastic force of the spring member 1, to both the first pressed body 101 and second pressed body 102. The spring member 1 does not necessarily contact the second pressed body 102 directly; and the spring member 1 and the second pressed body 102 may be caused to contact each other indirectly by provision of a pressure applying member, which conveys a load of the spring member 1 to the second pressed body 102, between the second pressed body 102 and the spring member 1. Furthermore, the spring member 1 may directly contact the first pressed body 101, or may indirectly contact the first pressed body 101 via a pressure applying member.

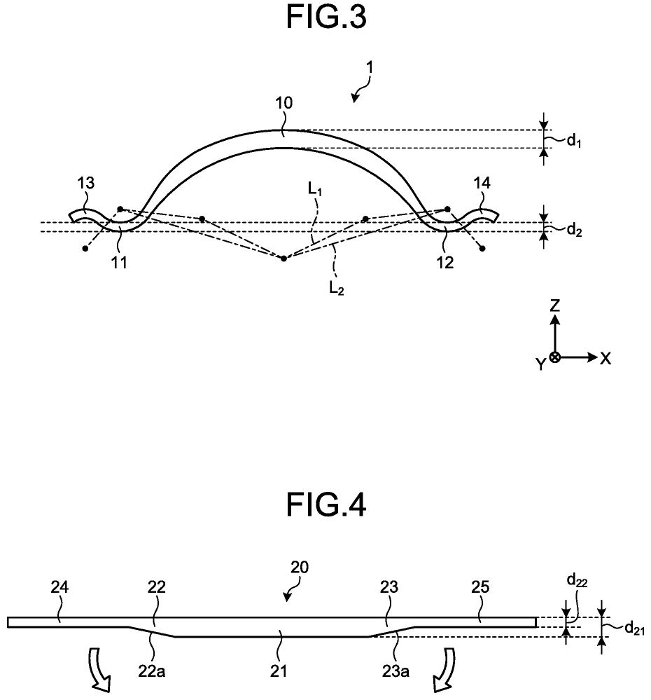

FIG. 2 is a perspective view illustrating a configuration of the spring member according to the first embodiment. FIG. 3 is a side view illustrating a configuration of the spring member according to the first embodiment. The spring member 1 is formed by using plate-like spring steel made of a carbon tool steel material (SK material), stainless steel (SUS), or the like. A base material for forming the spring member 1 preferably has a Young's modulus equal to or larger than 160 GPa and equal to or smaller than 220 GPa.

The spring member 1 is manufactured by bending a strip-like member formed of a single plate that partially differs in thickness. The single plate referred to herein means a plate formed of a single member, and not a plate having plural members integrated together by bonding or sticking. Hereinafter, in each member, a surface having a relatively large area will be referred to as a “principal surface”, and a surface orthogonal to the principal surface will be referred to as a “side surface”. Furthermore, a length between the principal surfaces (the length in a Z-direction in FIG. 3) of each member will be referred to as a “thickness”, and a length of each member in a direction (a Y-direction in FIG. 2) orthogonal to a curving direction of the principal surfaces will be referred to as a “width”. Hereinafter, description will be made on the assumption that the spring member 1 is formed of a base material having a uniform width, but the spring member 1 may be formed of a base material having different widths.

The spring member 1 has: a base portion 10 that has an outer margin forming a rectangular shape (a shape on an XY-plane in FIG. 2) and forms a curved shape along a principal surface thereof; an extended portion 11 that extends from one of end portions of the base portion 10, the end portions approaching each other due to curving of the base portion 10, the extended portion 11 being curved in a form inverse of a curving form of the base portion 10; an extended portion 12 that extends from the other one of the end portions of the base portion 10, the end portions approaching each other due to the curving of the base portion 10, the extended portion 12 being curved in a form inverse of the curving form of the base portion 10; a bent portion 13 that extends from an end portion of the extended portion 12, the end portion being at an end opposite to an end connected to the base portion 10, the bent portion 13 being curved in a form inverse of the curving form of the extended portion 11; and a bent portion 14 that extends from an end portion of the extended portion 12, the end portion being at an end opposite an end connected to the base portion 10, the bent portion 14 being curved in a form inverse of the curving form of the extended portion 12.

The base portion 10 is curved in an arc-shape having curvature centers on one side of principal surfaces that are opposite to each other in a plate thickness direction when viewed from the Y-direction (FIG. 3). The base portion 10 decreases in thickness toward end portions of the base portion 10, the end portions being connected to the extended portions 11 and 12. Therefore, a curving form of one of the principal surfaces of the base portion 10 is different from a curving form of the other principal surface; and a locus L₁ (hereinafter, also referred to as “one of the loci L₁”) formed of a collection of curvature center points of one of the principal surfaces and a locus L₂ (hereinafter, also referred to as “the other locus L₂”) formed of a collection of curvature center points of the other principal surface are different from each other. A collection of curvature center points referred to herein means a collection of curvature center points, which are plural points arbitrarily specified for each principal surface and are in plural areas provided along the curving direction. Furthermore, “the loci being the same” means that when the loci are superposed on each other, one of the loci L₁ and the other locus L₂ coincide with each other. That is, if “the loci are different from each other”, one of the loci L₁ and the other locus L₂ at least partially do not coincide with each other. In FIG. 3, when one of the loci L₁ and the other locus L₂ are superposed on each other, the loci L₁ and L₂ partially have a portion where the loci L₁ and L₂ do not coincide with each other. Specifically, the loci at portions of the base portion 10 are different from each other, the portions being connected to the extended portions 11 and 12. If the thickness is uniform, the loci coincide with each other. A portion of the base portion 10, the portion having the maximum width, is preferably a portion that comes into contact with the second pressed body 102, for example, a central portion along a direction (an X-direction), in which the base portion 10 is connected to the extended portions 11 and 12.

The base portion 10 applies a load to the second pressed body 102 by coming into contact with the second pressed body 102, at the central portion along a longitudinal direction thereof. Curvature of the base portion 10 is able to be designed according to an interval between the first pressed body 101 and the second pressed body 102, and a length thereof in the X-direction, as appropriate.

By coming into contact with the first pressed body 101, the extended portions 11 and 12 apply a load to the first pressed body 101. The extended portions 11 and 12 have thicknesses equivalent to each other, and this thickness d₂ of the extended portions 11 and 12 is smaller than a thickness d₁ of the connection direction central portion of the base portion 10 (see FIG. 3). The extended portions 11 and 12 may extend in a uniform thickness, or may decrease in thickness toward central portions of the extended portions 11 and 12 along a direction (the X-direction) in which the extended portions 11 and 12 extend from the base portion 10.

The bent portions 13 and 14 form end portions of the spring member 1, and are portions that are, for example, held by a user or engaged with a member. The bent portions 13 and 14 have thicknesses that are equivalent to each other, and the maximum thickness of the bent portions 13 and 14 may be equivalent to, smaller than, or larger than the thickness d₂ of the extended portions 11 and 12. The bent portions 13 and 14 may extend in a uniform thickness, or partially change in thickness.

As illustrated in FIG. 1, when the spring member 1 is arranged between the first pressed body 101 and the second pressed body 102, the base portion 10 applies a load to the second pressed body 102, and the extended portions 11 and 12 contact the first pressed body 101 and apply a load to the first pressed body 101. As the distance between the first pressed body 101 and the second pressed body 102 is decreased, the spring member 1 is elastically deformed, and applies, by means of elastic force due to the elastic deformation, pressure to both of the first pressed body 101 and the second pressed body 102.

As described above, since the spring member 1 is shaped to decrease in thickness toward the extended portions 11 and 12 from the central portion of the base portion 10; the curvature, at which the extended portions 11 and 12 are able to be bent, is able to be increased as compared to a case where the whole spring member 1 has a uniform thickness, for example, as compared to a case where the extended portions 11 and 12 have the thickness d₁ of the base portion 10, while the base portion 10 maintains the load applied to the second pressed body 102. By increasing the curvature of the extended portions 11 and 12, a proportion of the extended portions 11 and 12 in the spring member 1 is able to be decreased and a proportion of the base portion 10 in the spring member 1 is able to be increased. By the increase in the proportion of the base portion 10 in the spring member 1, length of the elastic stroke is able to be increased.

A ratio d₁/d₂ between the thickness d₁ of the connection direction central portion of the base portion 10 and the thickness d₂ of the extended portions 11 and 12 is preferably equal to or larger than 1.5 and equal to or smaller than 3.0. The thicknesses referred to herein mean the maximum thicknesses of the base portion 10 and the extended portions 11 and 12. The thickness d₂ may be the maximum thickness in the extended portions 11 and 12 and bent portions 13 and 14. If d₁/d₂ is smaller than 1.5, the difference between the thicknesses becomes small, and the effect of increasing the curvature of the extended portions 11 and 12 as described above may be unable to be obtained. Furthermore, if d₁/d₂ is larger than 3.0, the thickness of the connection direction central portion of the base portion 10 becomes too large and flexibility of the base portion 10 itself may be lost.

FIG. 4 is a side view illustrating a configuration of a material for manufacturing the spring member according to the first embodiment of the present invention. A base material 20 illustrated in FIG. 4 has: a base portion 21 extending in a uniform thickness; an inclined portion 22 extending from one longitudinal direction end of the base portion 21 and having an inclined surface 22a that is provided on one of principal surfaces thereof and is inclined with respect to an extending direction of the inclined portion 22; an inclined portion 23 extending from the other longitudinal direction end of the base portion 21 and having an inclined surface 23a that is provided on one of principal surfaces thereof and is inclined with respect to an extending direction of the inclined portion 23; an end portion 24 extending in a uniform thickness from an end portion of the inclined portion 22, the end portion being at an end opposite to an end connected to the base portion 21, the end portion 24 having a thickness d₂₂ smaller than a thickness d₂₁ of the base portion 21; and an end portion 25 extending in a uniform thickness from an end portion of the inclined portion 23, the end portion being at an end opposite to an end connected to the base portion 21, the end portion 25 having the thickness d₂₂ smaller than the thickness d₂₁ of the base portion 21. For example, the thickness d₂₁ is equivalent to the thickness d₁ described above, and the thickness d₂₂ is equivalent to the thickness d₂ described above.

The spring member 1 is manufactured by bending this base material 20 to sides (arrows illustrated in FIG. 4) where the inclined surfaces 22a and 23a face each other.

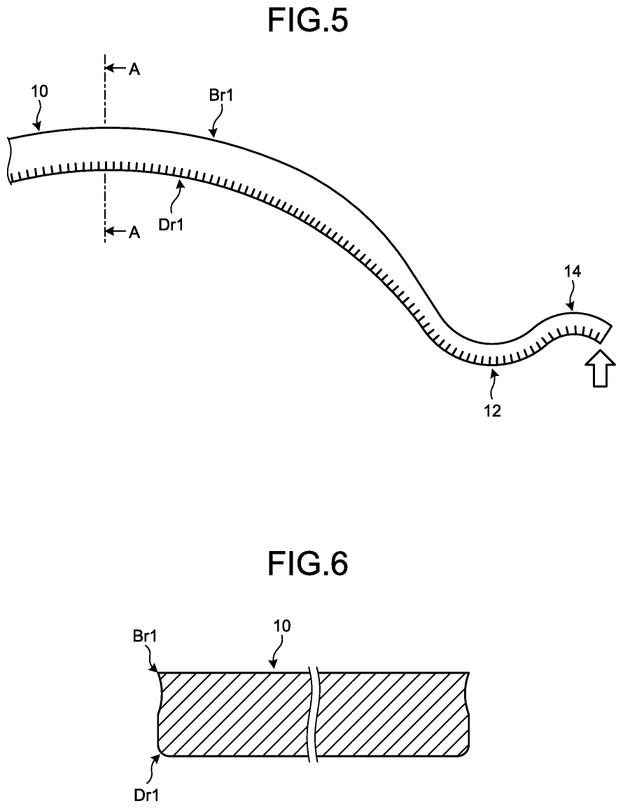

FIG. 5 is a side view illustrating a configuration of main parts of the spring member according to the first embodiment of the present invention. FIG. 6 is a sectional view along an A-A line illustrated in FIG. 5. As illustrated in FIG. 5, on a side surface of the spring member 1, a fracture surface Br1 is formed only at one principal surface side and a shear surface Dr1 is formed only at the other principal surface side. The “side surface” referred to herein means a side surface that is connected to the two opposite principal surfaces of the spring member 1 and is curved according to the curving forms of the base portion 10, the extended portions 11 and 12, and the bent portions 13 and 14. In the case illustrated in FIG. 5, the fracture surface Br1 is formed at the side where the base portion 10 and the bent portions 13 and 14 are convex, and the shear surface Dr1 is formed at the side where the extended portions 11 and 12 are convex. Because of this configuration, even if, for example, the spring member 1 is deformed such that curvature of the base portion 10 and the bent portions 13 and 14 is reduced by pushing up the bent portions 13 and 14 in the direction indicated by the arrow in FIG. 5 (upward in FIG. 5), stress is concentrated on the side where the shear surface Dr1 has been formed and tensile stress is generated. Therefore, even if tensile stress is generated at the side where the shear surface Dr1 has been formed, the spring member 1 is difficult to be broken, and as a result, the strength of the spring member 1 is able to be increased.

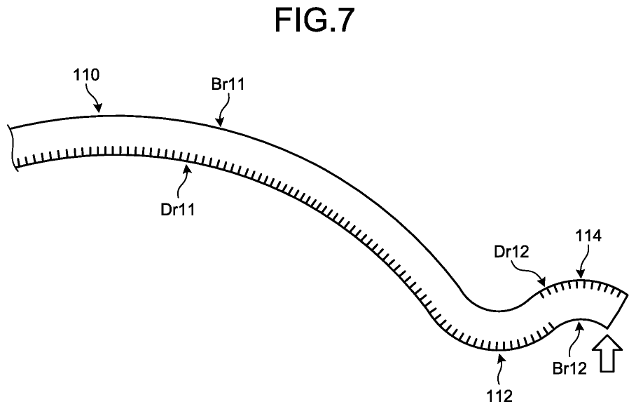

FIG. 7 is a side view illustrating a configuration of main parts of a conventional spring member. As illustrated in FIG. 7, the conventional spring member has, formed therein, fracture surfaces Br11 and Br12 and shear surfaces Dr11 and Dr12, at parts of both of its principal surfaces. In the case illustrated in FIG. 7, the fracture surfaces Br11 and Br12 are respectively formed at a side where a base portion 110 is convex and an extended portion (for example, an extended portion 112) is concave and at a side where a bent portion (for example, a bent portion 114) is convex, and the shear surfaces Dr11 and Dr12 are formed at a side where the base portion 110 is concave and the extended portion 112 is convex and at a side where the bent portion 114 is concave. Because of this configuration, when, for example, the spring member is deformed such that curvature of the base portion 110 and the bent portion 114 is reduced by pushing up the bent portion (the bent portion 114) in a direction of the arrow in FIG. 7 (upward in FIG. 7), stress is concentrated on the side where the fracture surface Br12 has been formed and tensile stress is generated. This concentration of the stress causes breakage of the spring member.

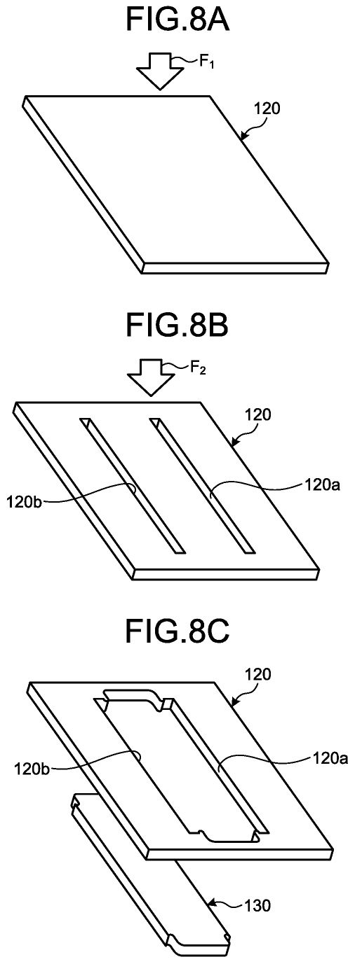

FIG. 8A to FIG. 8C are diagrams for explanation of a method of manufacturing a base material for forming a conventional spring member. The base material that forms the conventional spring member is obtained by punching holes in a plate-like material by means of a press from one side, and thereafter punching out the outer periphery by means of a press from the opposite direction.

Specifically, as illustrated in FIG. 8A, firstly, two slits (slits 120a and 120b) penetrating a plate-like material 120 from one of its principal surfaces to the other principal surface are formed by pressing the plate-like material 120 from the one principal surface side to the other principal surface side by means of a punch (see FIG. 8B). These slits 120a and 120b extend parallelly along the principal surfaces.

Thereafter, a base material 130 is punched out by pressing the plate-like member 120 in a direction of an arrow F₂, that is, in the same direction as the pressing direction for the slits 120a and 120b (see FIG. 8C). By this punching, the base material 130 is manufactured from the plate-like material 120. The base material 130 manufactured forms the above described spring member by being bent with predetermined curvature. The base material 130 illustrated in FIG. 8C has been turned upside down, relatively to the spring member illustrated in FIG. 7.

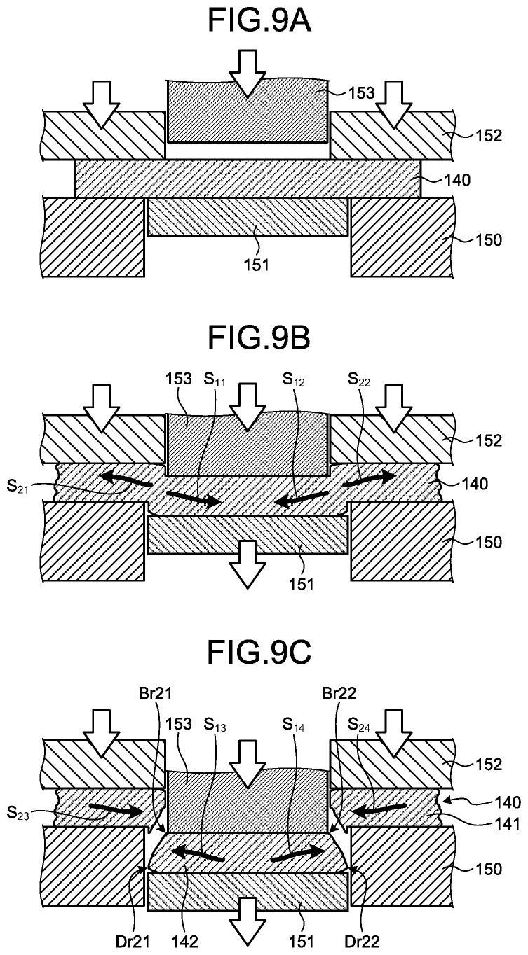

When slits are formed by pressing, the above described fracture surface and shear surface are generated according to the direction of the pressing. FIG. 9A to FIG. 9C are diagrams for explanation of a method of manufacturing a base material for forming a conventional spring member, and for explanation of cutting of a member by means of pressing. For example, in a state where a material 140 has been placed by means of a punch die 150 and a knockout 151; a stripper 152 and a punch 153 are brought closer to the material 140 from a side opposite to the placement surface, and the punch 153 is lowered while the stripper 152 holds the material 140 (see FIG. 9A).

As the punch 153 is continuously lowered, the knockout 151 is lowered while the material is deformed (see FIG. 9B). As this happens, crushing occurs and mutually escaping stresses S₁₁, S₁₂, S₂₁, and S₂₂ are generated in a boundary portion between: a portion of the material 140, the portion being held by the punch die 150 and the stripper 152; and a portion of the material 140, the portion being held by the knockout 151 and the punch 153.

As the punch 153 is lowered further, the material 140 is cut and divided into a first material 141 and a second material 142 (see FIG. 9C). After the material 140 has been cut, stresses S₁₃, S₁₄, S₂₃, and S₂₄ directed to the cut surfaces are generated in the portion of the material 140, the portion being held by the punch die 150 and the stripper 152, and in the portion of the material 140, the portion being held by the knockout 151 and the punch 153. The second material 142 that has been cut as described above has, for example, shear surfaces Dr21 and Dr22 forming curved surfaces at a surface of the second material 142, the surface being opposite to the contacting surface of the second material 142, the contacting surface contacting the punch 153, the curved surfaces having been formed by extension of the material 140 in association with the lowering of the punch 153. In contrast, the second material 142 has fracture surfaces Br21 and Br22 at the contacting surface of the second material 142, the contacting surface contacting the punch 153, the fracture surfaces Br21 and Br22 having been formed by fracture of the material 140 in association with the lowering of the punch 153.

Since the base material 130 has been conventionally formed by performing punching from two opposite directions as described above, the fracture surface and shear surface at both longitudinal direction end portions of the base material 130 are formed on the surface opposite to the surface where the fracture surface and shear surface are formed at a portion other than these end portions. Thereby, the fracture surfaces Br11 and Br12 and shear surfaces Dr11 and Dr12 as illustrated in FIG. 7 have been formed.

According to the above described first embodiment, in the spring member 1, since the thickness of the extended portions 11 and 12 is made small as compared to the thickness of the base portion 10, and the curvature, at which the extended portions 11 and 12 are able to be bent, is made large as compared to the curvature, at which the base portion 10 is able to be bent, the elastic stroke relative to a load on the first pressed body 101 and second pressed body 102 is long, and a target is able to be pressed while a uniform stress is being generated.

Conventionally known as another method of increasing the length of the elastic stroke is a method where stress is uniformized and the length of elastic stroke is increased by making a target to be pressed tapered at a side where the target to be pressed comes into contact with the first pressed body 101. In this method, the closer the width of the distal end portion is to zero, the higher the stress uniformization effect is. However, when this method is additionally used, the tapered distal end portion comes into contact with the target to be pressed, and thus there is a problem that the surface pressure is increased due to the decrease in the contact area. In contrast, when the spring member 1 according to the first embodiment is formed of a member having a uniform width, the increase in the surface pressure is able to be prevented.

In the above described spring member 1 according to the first embodiment, the width of the extended portion 11 and bent portion 13, and the width of the extended portion 12 and bent portion 14 may be continuously or stepwisely increased from the sides connected the base portion 10 to end portions of the bent portions 13 and 14, the end portions being at sides opposite to sides respectively connected to the extended portions 11 and 12, or the width of the bent portions 13 and 14 may be made larger than the widths of the base portion 10 and extended portions 11 and 12.

Furthermore, the above described spring member 1 according to the first embodiment may have a hole provided therein, the hole penetrating therethrough from one of the principal surfaces to the other principal surface. By the formation of the hole, weight reduction of the spring member 1 is able to be achieved.

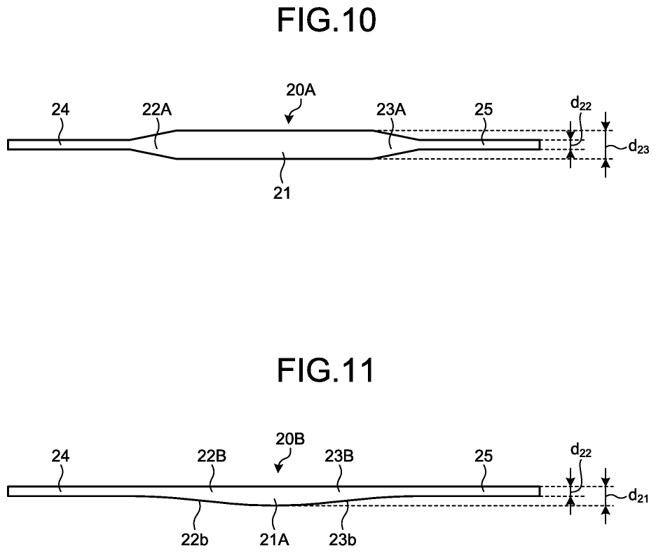

Furthermore, according to the above description of the first embodiment, the spring member 1 is formed by using the base material 20 having the inclined surfaces 22a and 23a provided on one of the principal surfaces, but the first embodiment is not limited to this formation. FIG. 10 and FIG. 11 are side views illustrating other examples of the base material for manufacturing the spring member according to the first embodiment of the present invention. For example, as illustrated in FIG. 10, a base material 20A may be used, the base material 20A having, instead of the above described base portion 21 and inclined portions 22 and 23: a base portion 21 having a thickness d₂₃; and inclined portions 22A and 23A each having two opposite principal surfaces each having an inclined surface. When a spring member is manufactured by using this base material 20A, a locus formed of a collection of curvature center points of one of principal surfaces of its base portion (for example, the base portion 10) and a locus formed of a collection of curvature center points of the other principal surface are different from each other.

Furthermore, as illustrated in FIG. 11, a base material 20B may be used, the base material 20B having, instead of the above described base portion 21 and inclined portions 22 and 23: a base portion 21A that continuously decreases in thickness from a longitudinal direction central portion thereof on one of principal surfaces thereof; an inclined portion 22B, which extends from one longitudinal direction end of the base portion 21A and has an inclined surface 22b provided on one of principal surfaces thereof and inclined with respect to an extending direction of the inclined portion 22B; and an inclined portion 23B, which extends from the other longitudinal direction end of the base portion 21A and has an inclined surface 23b provided on one of principal surfaces thereof and inclined with respect to an extending direction of the inclined portion 23B. In the base material 20B, for example, the maximum thickness of the base portion 21A is d₂₁ (>d₂₂).

In the base material 20B illustrated in FIG. 11, thickness on the other principal surface of the base portion 21A may continuously decrease from the central portion. Furthermore, FIG. 11 illustrates an example where the central portion of the base portion 21A, the surface where the base portion 21A and the inclined surface 22b are connected, and the surface where the base portion 21A and the inclined surface 23b are connected form a smooth curved surface; but the central portion of the base portion 21A, the surface where the base portion 21A and the inclined surface 22b are connected, the surface where the base portion 21A and the inclined surface 23b are connected, the surface where the inclined surface 22b and the end portion 24 are connected, and the surface where the inclined surface 23b and the end portion 25 are connected may be configured to have corner portions where planes intersect each other (see, for example, FIG. 10).

### Second Embodiment

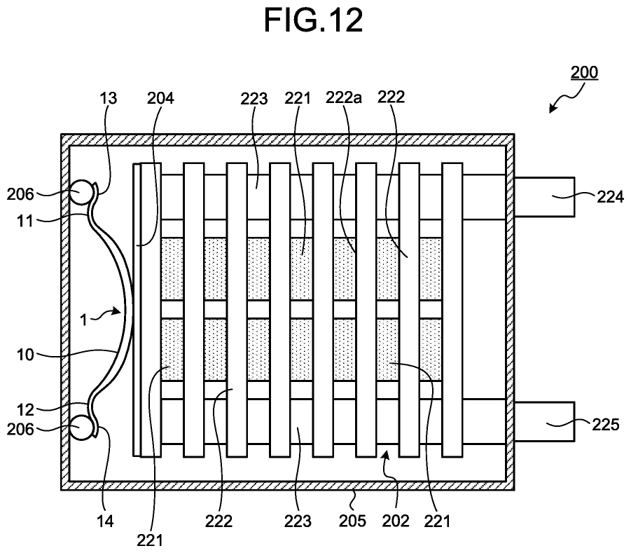

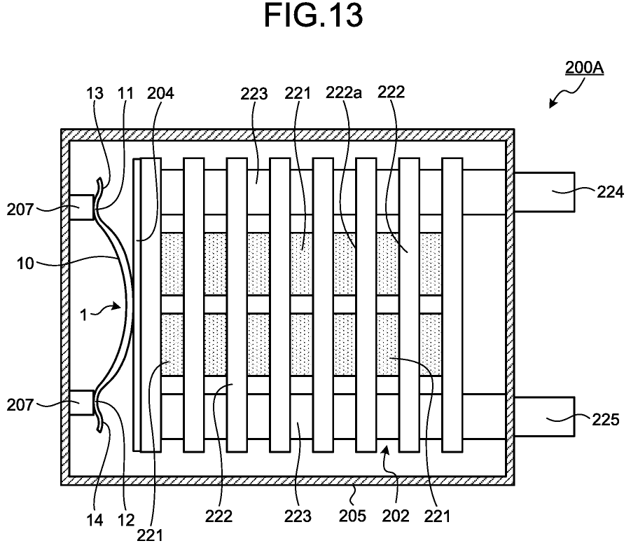

Next, a second embodiment of the present invention will be described. FIG. 12 is a schematic diagram illustrating a configuration of main parts of a power converting apparatus according to the second embodiment of the present invention. Any components that are the same as those illustrated in FIG. 1 and the like will be assigned with the same reference signs. Described as an application example of the spring member 1 is the power converting apparatus according to the second embodiment, the power converting apparatus serving as a pressing unit. A power converting apparatus 200 illustrated in FIG. 12 is, for example, an apparatus that generates driving current to be fed to a driving motor for an electric vehicle.

The power converting apparatus 200 includes: a semiconductor stack unit (first pressed body) 202 including semiconductor elements; the spring member 1 that presses the semiconductor stack unit 202 from one of side surfaces thereof; an abutting plate 204 that is interposed between the semiconductor stack unit 202 and the spring member 1 and is plate-like; and a housing (second pressed body) 205 that accommodates therein the semiconductor stack unit 202, the spring member 1, and the abutting plate 204. Additionally to those illustrated in FIG. 12, the power converting apparatus 200 has a control circuit or the like that controls semiconductor modules 221. The housing 205 has, provided therein, supporting members 206, which hold and support the spring member 1 between the supporting members 206 and the abutting plate 204 and are cylindrical.

The semiconductor stack unit 202 has a structure where the semiconductor modules 221 and cooling tubes 222 are alternately stacked on each other. In the case illustrated in FIG. 12, two semiconductor modules 221 are arranged between cooling tubes 222 adjacent to each other along the stacking direction.

The semiconductor module 221 is integrally formed by: having an IGBT element and a flywheel diode element that are arranged between a pair of radiator plates, the IGBT element being for electric power supply, the flywheel diode element being provided for smoothly rotating the motor; and being sealed by resin such that the pair of radiator plates are exposed.

The cooling tube 222 is a flat-shaped tube having a refrigerant flow channel inside. For example, a cooling medium, such as: a natural refrigerant, such as water or ammonia; water mixed with an ethylene glycol-based antifreeze; a fluorocarbon-based refrigerant, such as Fluorinert; a fluorocarbon refrigerant, such as HCFC123 or HFC134a; an alcohol-based refrigerant, such as methanol or alcohol; or a ketone-based refrigerant, such as acetone, is caused to flow through the refrigerant flow channel.

The plural cooling tubes 222 are connected to one another via connecting pipes 223 extending along the stacking direction of the semiconductor stack unit 202. End portions of the connecting pipes 223 have, provided therein, a refrigerant introduction port 224 and a refrigerant discharge port 225, which are connected to the cooling tube 222 arranged at these end portions. The cooling tubes 222, the connecting pipes 223, the refrigerant introduction port 224, and the refrigerant discharge port 225 are realized by use of, for example, aluminum.

Principal surfaces 222a of the cooling tubes 222 are in close contact with the radiator plates of the semiconductor modules 221, due to the pressing force from the spring member 1. Thereby, heat exchange between the semiconductor modules 221 and the cooling tubes 222 is able to achieved.

The spring member 1 is supported by: the base portion 10 abutting the abutting plate 204; and the bent portions 13 and 14 being engaged with the supporting members 206.

According to the above described second embodiment, by use of the spring member 1, the semiconductor stack unit 202 is able to be pressed in its stacking direction by sufficient pressing force. Therefore, cooling efficiency of the semiconductor stack unit 202 by means of the cooling tubes 222 is able to be improved.

### Modified Example of Second Embodiment

FIG. 13 is a schematic diagram illustrating a configuration of main parts of a power converting apparatus according to a modified example of the second embodiment of the present invention. According to the above description of the second embodiment, the spring member 1 is supported by the curved side surfaces of the cylindrical supporting members 206, but in this modified example, the spring member 1 is supported by end portions each forming a plane.

A power converting apparatus 200A according to this modified example includes, instead of the supporting members 206 of the above described power converting apparatus 200, supporting members 207. Inside the housing 205, the supporting members 207 each extend in a pillar-shape and each have an extending direction distal end forming a plane.

The spring member 1 is sandwiched by: the base portion 10 abutting the abutting plate 204; and the extended portions 11 and 12 abutting the supporting members 207.

According to the above described modified example of the second embodiment also, by using the spring member 1, the semiconductor stack unit 202 is able to be pressed in its stacking direction by sufficient pressing force. Therefore, cooling efficiency of the semiconductor stack unit 202 by means of the cooling tubes 222 is able to be improved.

### Third Embodiment

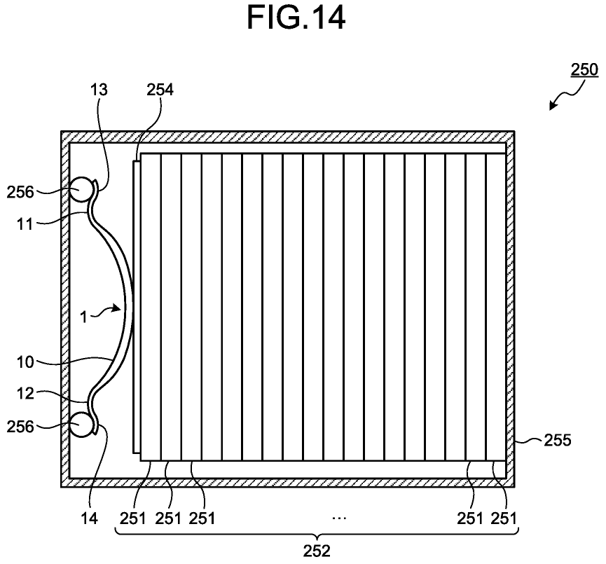

Described next is a third embodiment of the present invention. FIG. 14 is a schematic diagram illustrating a configuration of main parts of an electric double layer capacitor according to the third embodiment of the present invention. Any components that are the same as those illustrated in FIG. 1 and the like will be assigned with the same reference signs. Described as another example of the application example of the spring member 1 is the electric double layer capacitor according to the third embodiment, the electric double layer capacitor serving as a pressing unit.

An electric double layer capacitor 250 according to the third embodiment of the present invention includes: a cell stack (first pressed body) 252 including plural package cells 251; the spring member 1 that presses the cell stack 252 from one of side surfaces thereof; an abutting plate 254 that is interposed between the cell stack 252 and the spring member 1 and is plate-like; and a housing (second pressed body) 255 that accommodates therein the cell stack 252, the spring member 1, and the abutting plate 254. The housing 255 has, provided therein, supporting members 256, which hold and support the spring member 1 between the supporting members 256 and the abutting plate 254 and are cylindrical. The electric double layer capacitor 250 has, additionally to those illustrated in FIG. 14, connection terminals and the like to an external circuit. The cell stack 252 is electrically connected to the connection terminals to the external circuit.

The cell stack 252 is formed by stacking the plural package cells 251 together. Each of the package cells 251 has an innermost layer and an outermost layer that are formed of insulating films, and includes a positive collector electrode and a negative collector electrode. Each of the package cells 251 accommodates therein, together with an electrolyte, a stack having plural collector electrodes placed on top of one another via separators. A positive electrode terminal and a negative electrode terminal of each of the collector electrodes are respectively connected to the positive collector electrode and the negative collector electrode. The plural package cells 251 are connected in series by connection between positive collector electrodes and negative collector electrodes of adjacent ones of the package cells 251 via connection terminals.

The spring member 1 is supported by: the base portion 10 abutting the abutting plate 254; and the bent portions 13 and 14 engaging with the supporting members 256.

According to the above described third embodiment, by the spring member 1 pressing the cell stack 252 of the electric double layer capacitor 250 in its stacking direction and limiting expansion of the polarizable electrode, the energy density per unit volume is able to be improved.

A pressing unit, to which the spring member 1 according to the first embodiment is applied, may be any pressing unit that has the spring member 1 arranged between a first pressed body and a second pressed body and presses the first pressed body and the second pressed body by means of the spring member 1; although the power converting apparatus according to the above described second embodiment is an example of a pressing unit that requires pressing by the spring member 1, and the electric double layer capacitor according to the above described third embodiment is another example of the pressing unit that requires pressing by means of the spring member 1.

The present invention may thus include various embodiments and the like not described herein, and various design changes and the like within the scope not departing from the technical ideas specified by the claims may be made.

### INDUSTRIAL APPLICABILITY

As described above, a pressing structure and a pressing unit according to the present invention have a long elastic stroke relative to a load and are suitable for pressing a target while generating a uniform stress. Reference Signs List

1 SPRING MEMBER

10, 21, 21A BASE PORTION

11, 12 EXTENDED PORTION

13, 14 BENT PORTION

20, 20A, 20B BASE MATERIAL

22, 22A, 22B, 23, 23A, 23B INCLINED PORTION

24, 25 END PORTION

100 PRESSING STRUCTURE

101 FIRST PRESSED BODY

102 SECOND PRESSED BODY

200 POWER CONVERTING APPARATUS

202 SEMICONDUCTOR STACK UNIT

204, 254 CONTACTING PLATE

205, 255 HOUSING

221 SEMICONDUCTOR MODULE

222 COOLING TUBE

223 CONNECTING PIPE

224 REFRIGERANT INTRODUCTION PORT

225 REFRIGERANT DISCHARGE PORT

250 ELECTRIC DOUBLE LAYER CAPACITOR

251 PACKAGE CELL

252 CELL STACK

1. A pressing structure that is arranged between a first pressed body and a second pressed body opposite to the first pressed body and presses the first pressed body and the second pressed body, the pressing structure comprising:
a spring member including:
a base portion formed of a single strip-like member and having a curved principal surface;
two extended portions extending respectively from end portions of the base portion and curved in a form inverse of a curving form of the base portion; and
two bent portions extending respectively from end portions of the two extended portions, the end portions being at sides opposite to sides connected to the base portion, the two bent portions being curved in a form inverse of the curving form of the extended portions, wherein
a maximum thickness of the extended portions and bent portions is smaller than a maximum thickness of the base portion.

2. The pressing structure according to claim 1, wherein the base portion decreases in thickness toward the extended portions.

3. The pressing structure according to claim 2, wherein a locus formed of a collection of curvature center points of one of principal surfaces of the base portion and a locus formed of a collection of curvature center points of the other principal surface are different from each other.

4. The pressing structure according to claim 1, wherein a ratio, d₁/d₂, between the maximum thickness d₁ of the base portion and the maximum thickness d₂ of the extended portions and bent portions is equal to or larger than 1.5 and equal to or smaller than 3.0.

5. The pressing structure according to claim 1, wherein, on a side surface connected to two opposite principal surfaces of the spring member, the side surface being at a side that is curved according to the curving forms of the base portion, extended portions, and bent portions, a shear surface is formed only on a principal surface side where the base portion and bent portions are concave and a fracture surface is formed only on a principal surface side where the base portion and bent portions are convex.

6. A pressing unit, comprising:
a first pressed body;
a second pressed body arranged opposite to the first pressed body; and
the pressing structure according to claim 1 that is arranged between the first pressed body and the second pressed body and presses the first pressed body and the second pressed body.

7. The pressing unit according to claim 6, wherein the base portion decreases in thickness toward the extended portions.

8. The pressing unit according to claim 7, wherein a locus formed of a collection of curvature center points of one of principal surfaces of the base portion and a locus formed of a collection of curvature center points of the other principal surface are different from each other.

9. The pressing unit according to claim 6, wherein a ratio, d₁/d₂, between the maximum thickness d₁ of the base portion and the maximum thickness d₂ of the extended portions and bent portions is equal to or larger than 1.5 and equal to or smaller than 3.0.

10. The pressing unit according to claim 6, wherein, on a side surface connected to two opposite principal surfaces of the spring member, the side surface being at a side that is curved according to the curving forms of the base portion, extended portions, and bent portions, a shear surface is formed only on a principal surface side where the base portion and bent portions are concave and a fracture surface is formed only on a principal surface side where the base portion and bent portions are convex.
